(19) United States
(12) Patent Application Publication
(10) Pub. No.: US 2026/0223455 A1
(43) Pub. Date: Jul. 30, 2026

(54) ARRAY SUBSTRATE AND DISPLAY PANEL

(71) Applicant: Guangzhou China Star Optoelectronics Semiconductor Display Technology Co., Ltd., Guangzhou (CN)

(72) Inventors: Jun ZHAO, Guangzhou (CN); Bin ZHAO, Guangzhou (CN); Juncheng XIAO, Guangzhou (CN); Xiaolin YAN, Guangzhou (CN); Lei QIAO, Guangzhou (CN); Zhijiang ZHANG, Guangzhou (CN); Shuaiyi WANG, Guangzhou (CN); Daoping YU, Guangzhou (CN); Peng GAO, Guangzhou (CN)

(73) Assignee: Guangzhou China Star Optoelectronics Semiconductor Display Technology Co., Ltd., Guangzhou (CN)

(21) Appl. No.: 19/241,569

(22) Filed: Jun. 18, 2025

(30) Foreign Application Priority Data
Jan. 24, 2025 (CN) 202510121424.1

(51) Int. Cl. H10D 86/40; H10D 86/60

(52) U.S. Cl. CPC H10D 86/423; H10D 86/60

(57) ABSTRACT

The present disclosure provides an array substrate and a display panel. The array substrate includes a base substrate and a first transistor and a second transistor disposed on the base substrate. A mobility of a first active layer of the first transistor is different from a mobility of a second active layer of a second transistor. At most one gate insulating layer is provided between the first active layer and the second active layer, and the first active layer is located in a non-perpendicular direction of the second active layer. One of a first gate, the first active layer, and a first source of the first transistor is disposed in the same layer as a second gate of the second transistor.

### CROSS-REFERENCE TO RELATED APPLICATION

This application claims priority to Chinese Patent Application No. 202510121424.1, filed on January 24, 2025. The disclosure of the aforementioned application is incorporated herein by reference in its entirety.

### TECHNICAL FIELD

The present disclosure relates to the field of display technologies, and in particular, to an array substrate and a display panel.

### BACKGROUND

The hybrid device technology is a new backplane technology, which has high research and application value. With the continuous development and maturity of technology, the hybrid device technology is expected to become one of the mainstream display technologies in the future. However, there are many different types of thin film transistors on an array substrate using the hybrid device technology, resulting in a complex film structure, poor device stability, and high difficulty in mass production.

### SUMMARY

Embodiments of the present disclosure provide an array substrate, including a base substrate and a first transistor and a second transistor disposed on the base substrate. The first transistor includes a first active layer, a first gate, a first source, and a first drain. The second transistor includes a second active layer, a second gate, a second source, and a second drain. A mobility of the first active layer is different from a mobility of the second active layer, at most one gate insulating layer is provided between the first active layer and the second active layer, the first active layer is located in a non-perpendicular direction of the second active layer, one of the first gate, the first active layer, and the first source is disposed in a same layer as the second gate, and the first source, the first drain, the second source, and the second drain are disposed in a same layer.

Embodiments of the present disclosure also provide a display panel including the above array substrate.

### BRIEF DESCRIPTION OF THE DRAWINGS

In order to more clearly explain the embodiments or technical proposals in prior arts, the drawings that need to be used in the description of the embodiments or the prior art will be briefly introduced below. It is obvious that the drawings in the following description are only some embodiments of the invention, and for those skilled in the art, other drawings can be obtained according to these drawings without making creative labor.

FIG. 1 is a schematic diagram of a first cross-sectional structure of an array substrate according to embodiments of the present disclosure.

FIG. 2 is a schematic diagram of a second cross-sectional structure of an array substrate according to embodiments of the present disclosure.

FIG. 3 is a schematic diagram of a third cross-sectional structure of an array substrate according to embodiments of the present disclosure.

FIG. 4 is a schematic diagram of a fourth cross-sectional structure of an array substrate according to embodiments of the present disclosure.

FIG. 5 is a schematic diagram of a fifth cross-sectional structure of an array substrate according to embodiments of the present disclosure.

FIG. 6 is a schematic diagram of a sixth cross-sectional structure of an array substrate according to embodiments of the present disclosure.

FIG. 7 is a schematic diagram of a seventh cross-sectional structure of an array substrate according to embodiments of the present disclosure.

### DETAILED DESCRIPTION

The following description of each embodiment is made with reference to the accompanying drawings to illustrate specific embodiments in which the present disclosure may be practiced. References to orientational terms in the present disclosure, such as “top”, “bottom”, “front”, “rear”, “left”, “right”, “inner”, “outer”, “side”, etc., are merely orientations with reference to the appended drawings. Accordingly, orientational terms used are intended to illustrate and understand the present disclosure, and are not intended to limit the present disclosure. In the drawings, structurally similar units are denoted by the same reference numerals. In the drawings, thicknesses of some layers and areas are exaggerated for clarity of understanding and ease of description. That is, dimensions and thicknesses of each component shown in the drawings are arbitrarily shown, but the present disclosure is not limited thereto.

Please refer to FIG. 1 to FIG. 7, which are schematic diagrams of a partial cross-sectional structure of an array substrate according to embodiments of the present disclosure. The array substrate 100 includes a base substrate 10 and a first transistor 20 and a second transistor 30 disposed on the base substrate 10. The first transistor 20 includes a first active layer 21, a first gate 22, a first source 23, and a first drain 24. The second transistor 30 includes a second active layer 31, a second gate 32, a second source 33, and a second drain 34.

A mobility of the first active layer 21 is different from a mobility of the second active layer 31. For example, the mobility of the first active layer 21 is greater than the mobility of the second active layer 31, so that the first transistor 20 and the second transistor 30 are of different types. At most one gate insulating layer is provided between the first active layer 21 and the second active layer 31, and the first active layer 21 is located in a non-perpendicular direction of the second active layer 31. One of the first gate 22, the first active layer 21, and the first source 23 is provided in the same layer as the second gate 32. The first source 23, the first drain 24, the second source 33, and the second drain 34 are provided in the same layer. As described above, by sharing part of film layers between the first transistor 20 and the second transistor 30, the film layer structure can be simplified, the stability of the device can be improved, and the yield can be improved.

In some embodiments, referring to FIG. 1, FIG. 1 is a schematic diagram of a first cross-sectional structure of the array substrate 100 according to embodiments of the present disclosure. The array substrate 100 includes a base substrate 10 and a first transistor 20 and a second transistor 30 disposed on the base substrate 10. The first transistor 20 and the second transistor 30 belong to different types. For example, the first transistor 20 includes a first active layer 21, the second transistor 30 includes a second active layer 31, and a mobility of the first active layer 21 is greater than a mobility of the second active layer 31.

Materials of the first active layer 21 and the second active layer 31 both include a metal oxide semiconductor material. For example, the materials of the first active layer 21 and the second active layer 31 are the same metal oxide semiconductor material, and doping different elements in the metal oxide semiconductor material can change the mobility of the metal oxide semiconductor material. For example, doping tin element in the metal oxide semiconductor material of the first active layer 21 can improve the mobility of the first active layer 21.

The first transistor 20 and the second transistor 30 may be located in a same sub-pixel circuit, or may be located in different sub-pixel circuits, or one of the first transistor 20 and the second transistor 30 is located in the sub-pixel circuit and the other is located in another circuit, such as the other is located in a gate on array (GOA) circuit, and the present disclosure is not limited thereto, for example, the first transistor 20 and the second transistor 30 are both located in a GOA circuit.

Referring to FIG. 1, the first transistor 20 further includes a first source 23, a first drain 24, and a first gate 22 located on one side of the first active layer 21 away from the base substrate 10, and the first gate 22 is disposed in a same layer as the first source 23 and the first drain 24. It should be noted that the term "disposed in a same layer" in the present disclosure means that at least two different structures are arranged in the same layer by patterning a film layer formed of the same material in the preparation process. For example, the first gate 22, the first source 23, and the first drain 24 in this embodiment are obtained by patterning a same conductive film layer, thus the first gate 22 is provided in the same layer as the first source 23 and the first drain 24.

The second transistor 30 includes a second source 33 and a second drain 34 located on one side of the second active layer 31 away from the base substrate 10, and a second gate 32 located on one side of the second active layer 31 close to the base substrate 10. The second active layer 31 is located on the side of the first active layer 21 away from the base substrate 10. The second source 33 and the second drain 34 are provided in the same layer as the first source 23 and the first drain 24. The second gate 32 is provided in the same layer as the first active layer 21.

Specifically, a first gate insulating layer 40 is provided between the first active layer 21 and the second active layer 31. A material of the first gate insulating layer 40 includes an inorganic material such as silicon oxide and silicon nitride. The first gate insulating layer 40 covers the first active layer 21 and the second gate 32.

The second active layer 31, the first source 23, the first drain 24, and the first gate 22 are all located on the side of the first gate insulating layer 40 away from the first active layer 21, that is, on the first gate insulating layer 40. The first source 23 and the first drain 24 are respectively connected to the first active layer 21 through via holes on the first gate insulating layer 40. The first gate 22 is provided corresponding to a channel portion of the first active layer 21. The second gate 32 is provided corresponding to at least a channel portion of the second active layer 31. The second source 33 and the second drain 34 are located on one side of the second active layer 31 away from the first active layer 21. The second source 33 and the second drain 34 are directly disposed on the second active layer 31.

In some embodiments, the array substrate 100 further includes a first light shielding portion 25 located on one side of the first active layer 21 close to the base substrate 10, that is, the first light shielding portion 25 is located between the first active layer 21 and the base substrate 10. The first light shielding portion 25 is provided corresponding to the first active layer 21, and is configured to shield the first active layer 21 from light. A material of the first light shielding portion 25 includes a metal material having a light shielding property or a non-metal material having a light shielding property, such as a black matrix or the like.

The first light shielding portion 25 is provided on the base substrate 10. The array substrate 100 further includes a buffer layer 11 covering the first light shielding portion 25 and the base substrate 10. The first active layer 21 is located on one side of the buffer layer 11 away from the first light shielding portion 25, that is, the first active layer 21 is located on the buffer layer 11.

Optionally, the base substrate 10 may be a rigid substrate or a flexible substrate. When the base substrate 10 is a rigid substrate, it may include a rigid substrate such as a glass substrate, a quartz substrate, or a silicon wafer. When the base substrate 10 is a flexible substrate, it may include a flexible substrate such as a polyimide (PI) film or an ultra-thin glass film.

The buffer layer 11 may prevent undesirable impurities or contaminants (e.g. moisture, oxygen, etc.) from diffusing from the base substrate 10 into elements that may be damaged by these impurities or contaminants, while also providing a planar top surface. The buffer layer 11 may be silicon nitride (SiNx), silicon oxide (SiOx), or a stack of silicon nitride and silicon oxide.

The array substrate 100 further includes a passivation layer 12 covering the first transistor 20 and the second transistor 30. Specifically, the passivation layer 12 covers the first source 23, the first drain 24, the first gate 22, the second source 33, the second drain 34, a part of the second active layer 31, and a part of the second gate insulating layer 50. The passivation layer 12 is configured to protect the first transistor 20 and the second transistor 30 and assists in flattening the undulating terrain of top surfaces of the first transistor 20 and the second transistor 30.

Of course, the array substrate 100 may further include a planarization layer, an electrode layer, or the like located on one side of the passivation layer 12 away from the first transistor 20 and the second transistor 30. The planarization layer covers the passivation layer 12 to flatten the undulating terrain of the top surfaces of the first transistor 20 and the second transistor 30. The electrode layer is provided on the planarization layer and is connected to the first transistor 20 or the second transistor 30 through a via hole on the planarization layer.

In this embodiment, the first transistor 20 and the second transistor 30 share one layer of the first gate insulating layer 40, which not only simplifies the film layer structure, but also facilitates the debugging of the device and improves the yield. Furthermore, the second gate 32 of the second transistor 30 is provided in the same layer as the first active layer 21 of the first transistor 20, and the second source 33 and the second drain 34 of the second transistor 30 are provided in the same layer as the first source 23, the first drain 24, and the first gate 22 of the first transistor 20, thereby further simplifying the film layer structure of the array substrate 100, improving the stability of the device, and improving the yield.

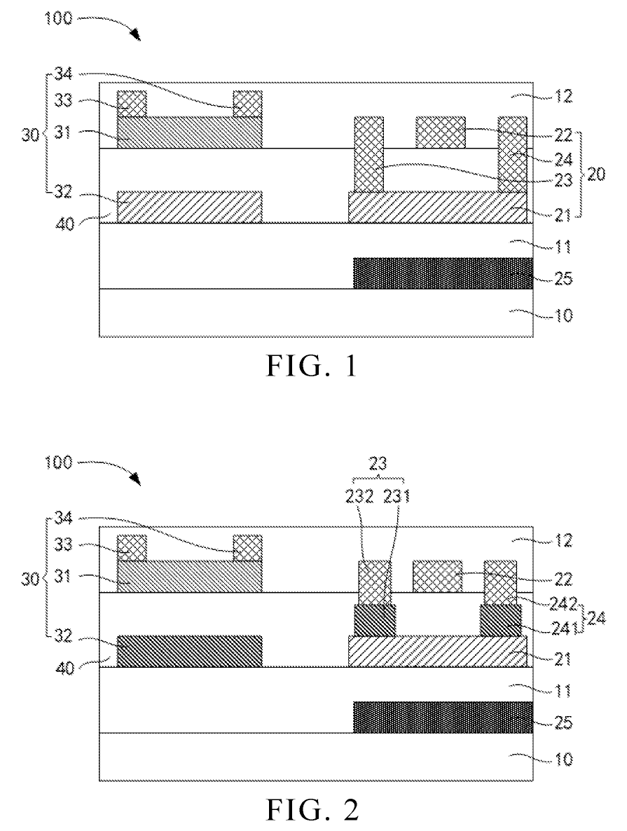

In some embodiments, referring to FIG. 2, FIG. 2 is a schematic diagram of a second cross-sectional structure of the array substrate 100 according to embodiments of the present disclosure. Different from the array substrate 100 illustrated in FIG. 1, the first source 23 in this embodiment includes a source portion 231 and a first bridge portion 232 connected to the source portion 231, the first drain 24 includes a drain portion 241 and a second bridge portion 242 connected to the drain portion 241, the source portion 231 connects the first bridge portion 232 and the first active layer 21, and the drain portion 241 connects the second bridge portion 242 and the first active layer 21. The first bridge portion 232 and the second bridge portion 242 are provided in the same layer as the second source 33, and the second gate 32 is provided in the same layer as the source portion 231 and the drain portion 241.

Specifically, the source portion 231 and the drain portion 241 are directly disposed on the first active layer 21. The first gate insulating layer 40 covers the source portion 231, the drain portion 241, a part of the first active layer 21, and a part of the buffer layer 11. Both the first bridge portion 232 and the second bridge portion 242 are located on one side of the first gate insulating layer 40 away from the first active layer 21. The first bridge portion 232 is connected to the source portion 231 through a via hole on the first gate insulating layer 40, and the second bridge portion 242 is connected to the drain portion 241 through a via hole on the first gate insulating layer 40.

The second gate 32 is provided in the same layer as the source portion 231 and the drain portion 241. At this time, the second gate 32 serves as the gate of the second transistor 30 and can shield the second active layer 31 of the second transistor 30 from light. The second source 33 and the second drain 34 are provided in the same layer as the first bridge portion 232, the second bridge portion 242, and the first gate 22.

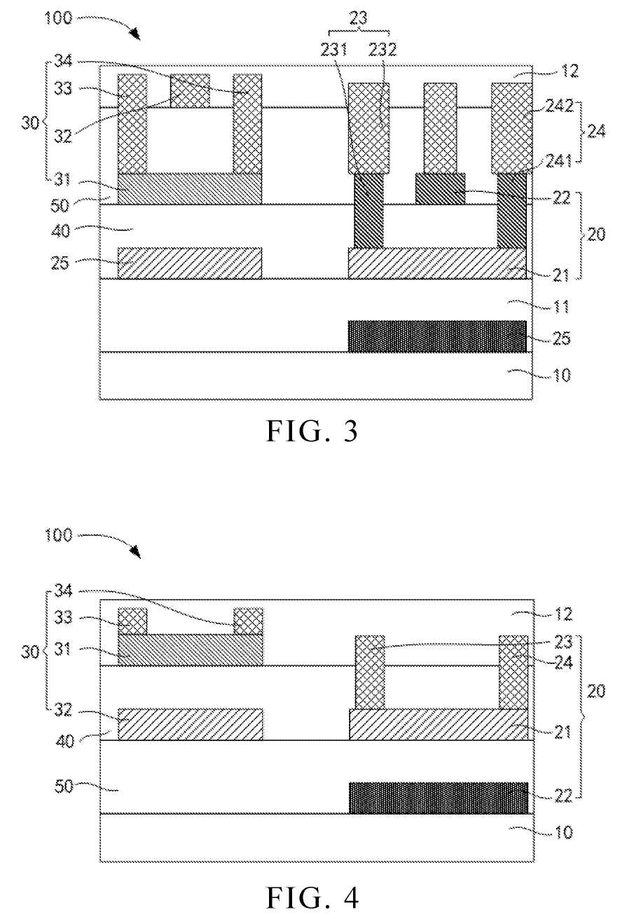

In some embodiments, referring to FIG. 3, FIG. 3 is a schematic diagram of a third cross-sectional structure of the array substrate 100 according to embodiments of the present disclosure. Different from the array substrate 100 illustrated in FIG. 1, the array substrate 100 further includes a second gate insulating layer 50 located on one side of the second active layer 31 away from the first active layer 21, the first gate 22 is located between the first gate insulating layer 40 and the second gate insulating layer 50, the second gate 32 located on one side of the second gate insulating layer 50 away from the second active layer 31, and the second gate 32 and the second source 33 are provided in the same layer. The second gate insulating layer 50 covers the second active layer 31, and the second source 33 and the second drain 34 are respectively connected to the second active layer 31 through via holes on the second gate insulating layer 50.

The first source 23 includes a source portion 231 and a first bridge portion 232 connected to the source portion 231, and the first drain 24 includes a drain portion 241 and a second bridge portion 242 connected to the drain portion 241. The source portion 231 and the drain portion 241 are provided in the same layer as the first gate 22, and the first bridge portion 232 and the second bridge portion 242 are provided in the same layer as the second gate 32.

The source portion 231 and the drain portion 241 are located on one side of the first gate insulating layer 40 away from the first active layer 21, and the source portion 231 and the drain portion 241 are respectively connected to the first active layer 21 through via holes on the first gate insulating layer 40. The second gate insulating layer 50 further covers the source portion 231 and the drain portion 241.

The first bridge portion 232 and the second bridge portion 242 are located on one side of the second gate insulating layer 50 away from the first gate insulating layer 40. The first bridge portion 232 and the second bridge portion 242 are connected to the source portion 231 and the drain portion 241 through via holes on the second gate insulating layer 50, respectively, so that the source portion 231 is connected between the first bridge portion 232 and the first active layer 21, and the drain portion 241 is connected between the second bridge portion 242 and the first active layer 21.

Optionally, the array substrate 100 further includes a first light shielding portion 25 and a second light shielding portion 35. The first light shielding portion 25 is located on one side of the first active layer 21 close to the base substrate 10 and disposed correspondingly to the first active layer 21, and the second light shielding portion 35 is disposed in the same layer as the first active layer 21 and disposed correspondingly to the second active layer 31.

In some embodiments, referring to FIG. 4, FIG. 4 is a schematic diagram of a fourth cross-sectional structure of the array substrate 100 according to embodiments of the present disclosure. Different from the array substrate 100 illustrated in FIG. 1, the array substrate 100 further includes a second gate insulating layer 50 located on one side of the first active layer 21 away from the second active layer 31. The first gate 22 is located on one side of the second gate insulating layer 50 away from the first active layer 21, the second gate 32 is located between the first gate insulating layer 40 and the second gate insulating layer 50, and the second gate 32 is disposed in the same layer as the first active layer 21.

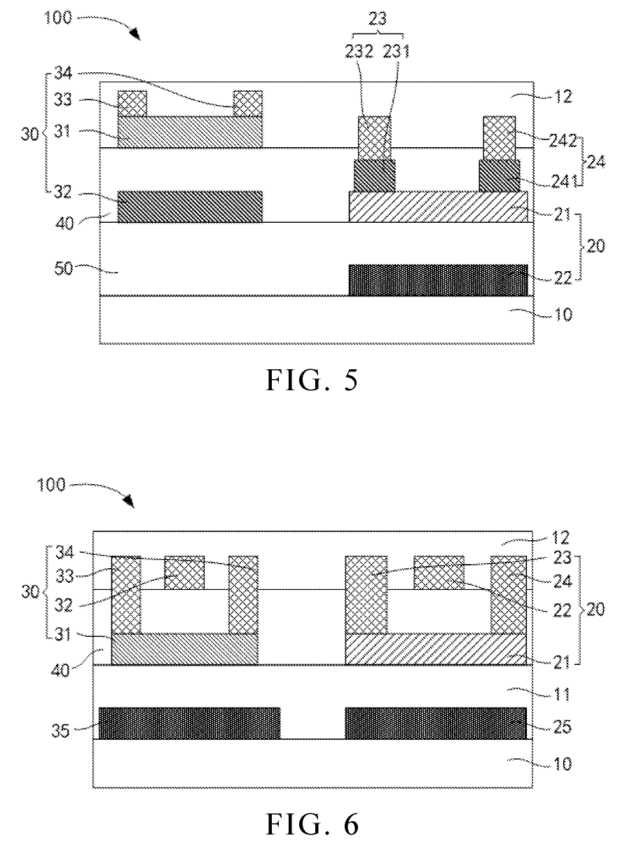

In some embodiments, referring to FIG. 5, FIG. 5 is a schematic diagram of a fifth cross-sectional structure of the array substrate 100 according to embodiments of the present disclosure. Different from the array substrate 100 illustrated in FIG. 1, the array substrate 100 further includes a second gate insulating layer 50 located on one side of the first active layer 21 away from the second active layer 31, the first gate 22 is located on one side of the second gate insulating layer 50 away from the first active layer 21, and the second gate 32 is located between the first gate insulating layer 40 and the second gate insulating layer 50.

The first source 23 includes a source portion 231 and a first bridge portion 232 connected to the source portion 231, and the first drain 24 includes a drain portion 241 and a second bridge portion 242 connected to the drain portion 241. The source portion 231 and the drain portion 241 are provided in the same layer as the second gate 32, and the first bridge portion 232 and the second bridge portion 242 are provided in the same layer as the second source 33.

In some embodiments, referring to FIG. 6, FIG. 6 is a schematic diagram of a sixth cross-sectional structure of the array substrate 100 according to embodiments of the present disclosure. Different from the array substrate 100 illustrated in FIG. 1, the first active layer 21 and the second active layer 31 are provided in the same layer, the first gate insulating layer 40 is provided between the first gate 22 and the first active layer 21, the first gate 22 is provided in the same layer as the second gate 32, the second gate 32 is provided in the same layer as the second source 33, and the second source 33 is located on one side of the first gate insulating layer 40 away from the second active layer 31.

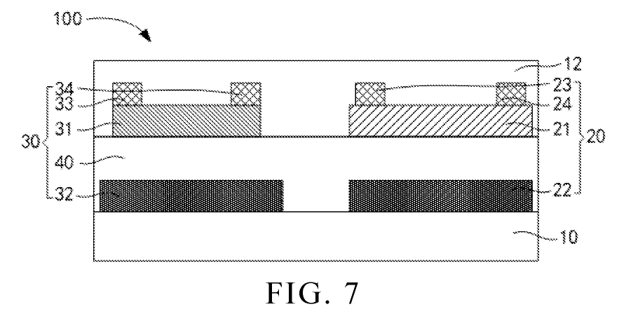

In some embodiments, referring to FIG. 7, FIG. 7 is a schematic diagram of a seventh cross-sectional structure of the array substrate 100 according to embodiments of the present disclosure. Different from the array substrate 100 illustrated in FIG. 1, the first active layer 21 and the second active layer 31 are provided in the same layer, the first gate insulating layer 40 is provided between the first gate 22 and the first active layer 21, the first gate 22 and the second gate 32 are provided in the same layer, and the first source 23 is located on one side of the first active layer 21 away from the first gate 22.

Based on the same inventive concept, embodiments of the present disclosure further provide a display panel including the array substrate according to one of the above embodiments. The display panel may be a type of display panel such as a light-emitting diode display panel or a liquid crystal display panel.

According to the above embodiments, it can be seen that:

In the array substrate and the display panel provided in the present disclosure, the array substrate includes the base substrate and the first transistor and the second transistor disposed on the base substrate, the mobility of the first active layer of the first transistor is different from the mobility of the second active layer of the second transistor, at most one gate insulating layer is provided between the first active layer and the second active layer, the first active layer is located in the non-perpendicular direction of the second active layer, and one of the first gate, the first active layer, and the first source of the first transistor is disposed in the same layer as the second gate of the second transistor. In this way, by sharing part of film layers between the first transistor and the second transistor, the film layer structure can be simplified, the stability of the device can be improved, and the yield can be improved.

In the above-described embodiments, the description of each embodiment has its own emphasis, and for parts not described in detail in a certain embodiment, please refer to the related description of other embodiments.

The embodiments of the present disclosure have been described in detail above, and the principles and embodiments of the present disclosure have been described herein by applying specific examples, and the description of the above embodiments is only for helping to understand the technical proposals and core ideas of the present disclosure. Those skilled in the art should understand that the technical proposals described in the above embodiments can still be modified, or some technical features can be equivalently replaced. However, these modifications or substitutions do not cause the essence of the corresponding technical proposals to deviate from the scope of the technical proposals of each embodiment of the present disclosure.

What is claimed is:

1. An array substrate, comprising a base substrate and a first transistor and a second transistor disposed on the base substrate;
wherein the first transistor comprises a first active layer, a first gate, a first source, and a first drain;
the second transistor comprises a second active layer, a second gate, a second source, and a second drain; and
a mobility of the first active layer is different from a mobility of the second active layer, at most one gate insulating layer is provided between the first active layer and the second active layer, the first active layer is located in a non-perpendicular direction of the second active layer, one of the first gate, the first active layer, and the first source is disposed in a same layer as the second gate, and the first source, the first drain, the second source, and the second drain are disposed in a same layer.

2. The array substrate according to claim 1, wherein materials of the first active layer and the second active layer each comprises a metal oxide semiconductor material.

3. The array substrate according to claim 1, wherein the second active layer is located on one side of the first active layer away from the base substrate, a first gate insulating layer is provided between the first active layer and the second active layer, and the second source and the second drain are located on one side of the second active layer away from the first active layer.

4. The array substrate according to claim 3, wherein the first gate is disposed on a same layer as the first source, the second gate is disposed in a same layer as the first active layer, and the first source and the first drain are located on one side of the first gate insulating layer away from the first active layer.

5. The array substrate according to claim 3, wherein the first source comprises a source portion and a first bridge portion connected to the source portion, the first drain comprises a drain portion and a second bridge portion connected to the drain portion, the source portion connects the first bridge portion and the first active layer, and the drain portion connects the second bridge portion and the first active layer; and
the first bridge portion and the second bridge portion are provided in a same layer as the second source, and the second gate is provided in a same layer as the source portion and the drain portion.

6. The array substrate according to claim 3, further comprising a second gate insulating layer disposed on one side of the second active layer away from the first active layer, wherein the first gate is located between the first gate insulating layer and the second gate insulating layer, the second gate is located on one side of the second gate insulating layer away from the second active layer, and the second gate is disposed in a same layer as the second source.

7. The array substrate according to claim 6, wherein the first source comprises a source portion and a first bridge portion connected to the source portion, the first drain comprises a drain portion and a second bridge portion connected to the drain portion, the source portion and the drain portion are provided in a same layer as the first gate, and the first bridge portion and the second bridge portion are provided in a same layer as the second gate.

8. The array substrate according to claim 6, further comprising a first light shielding portion and a second light shielding portion, wherein the first light shielding portion is disposed on one side of the first active layer close to the base substrate and disposed correspondingly to the first active layer, and the second light shielding portion is disposed in a same layer as the first active layer and disposed correspondingly to the second active layer.

9. The array substrate according to claim 3, further comprising a second gate insulating layer disposed on one side of the first active layer away from the second active layer, wherein the first gate is disposed on one side of the second gate insulating layer away from the first active layer, the second gate is located between the first gate insulating layer and the second gate insulating layer, and the second gate is disposed in a same layer as the first active layer.

10. The array substrate of claim 3, further comprising a second gate insulating layer disposed on one side of the first active layer away from the second active layer, wherein the first gate is disposed on one side of the second gate insulating layer away from the first active layer, the second gate is located between the first gate insulating layer and the second gate insulating layer; and
the first source comprises a source portion and a first bridge portion connected to the source portion, the first drain comprises a drain portion and a second bridge portion connected to the drain portion, the source portion and the drain portion are provided in a same layer as the second gate, and the first bridge portion and the second bridge portion are provided in a same layer as the second source.

11. The array substrate according to claim 1, wherein the first active layer and the second active layer are disposed in a same layer, a first gate insulating layer is provided between the first gate and the first active layer, the first gate is disposed in a same layer as the second gate, the second gate is disposed in a same layer as the second source, and the second source is disposed on one side of the first gate insulating layer away from the second active layer.

12. The array substrate according to claim 1, wherein the first active layer and the second active layer are disposed in a same layer, a first gate insulating layer is provided between the first gate and the first active layer, the first gate and the second gate are disposed in a same layer, and the first source is disposed on one side of the first active layer away from the first gate.

13. A display panel, comprising the array substrate of claim 1.
